(19) United States
(12) Patent Application Publication
(10) Pub. No.: US 2026/0147212 A1
(43) Pub. Date: May 28, 2026

(54) LIGHT SOURCE DEVICE AND DISPLAY DEVICE

(71) Applicant: NICHIA CORPORATION, Anan-shi (JP)

(72) Inventor: Takashi SASAMURO, Chino-shi (JP)

(73) Assignee: NICHIA CORPORATION, Anan-shi (JP)

(21) Appl. No.: 19/401,589

(22) Filed: Nov. 26, 2025

(30) Foreign Application Priority Data
Nov. 28, 2024 (JP) 2024-206956

(51) Int. Cl. G02B 27/01; G02B 1/00; G02B 3/04; G02B 27/00; G02B 27/10; H01S 5/02253; H01S 5/02255

(52) U.S. Cl. CPC G02B 27/0172; G02B 1/002; G02B 27/0025; G02B 27/102; H01S 5/02253; H01S 5/02255; G02B 3/04; G02B 2027/011; G02B 2027/0112

(57) ABSTRACT

A light source device includes: first to third semiconductor laser elements configured to respectively emit first to third laser beams of first to third colors different from one another; a lens configured to collimate the first to third laser beams; a housing having an opening through which the first to third laser beams transmitted through the lens pass and containing the first to third semiconductor laser elements and the lens; and a light-transmissive member covering the opening, having a second light incident surface and a second light exit surface, and allowing the first to third laser beams to pass therethrough. The light-transmissive member has first and second diffraction gratings on the second light incident surface to deflect the third and second laser beams so that their optical axes come closer to an optical axis of the first laser beam than before passing through the second light incident surface.

### CROSS-REFERENCE TO RELATED APPLICATION

This application claims priority to Japanese Patent Application No. 2024-206956, filed on Nov. 28, 2024, the disclosure of which is hereby incorporated by reference in its entirety.

### TECHNICAL FIELD

The present disclosure relates to a light source device and a display device.

### BACKGROUND

Light source devices that emit laser beams and display devices including such light source devices are conventionally known. For example, Japanese Patent Publication No. 2021-174991 discloses three lasers disposed in a housing cap and configured to emit three different colors of light and an optical unit disposed outward of a laser source and configured to align the laser beams on the same axis. In this optical unit, for example, a beam collimator and a dichroic beam splitter or beam combiner are disposed to correspond each of the lasers.

### SUMMARY

An object of certain embodiments of the present disclosure is to provide a light source device that emits laser beams whose optical axes are closer to each other than optical axes at a region where the laser beams are emitted from respective semiconductor laser elements.

A light source device according to an embodiment of the present disclosure includes: a first semiconductor laser element configured to emit a first laser beam of a first color; a second semiconductor laser element configured to emit a second laser beam of a second color different from the first color; a third semiconductor laser element configured to emit a third laser beam of a third color different from the first color and the second color; a lens having a first light incident surface and a first light exit surface and being configured to collimate the first laser beam, the second laser beam, and the third laser beam; a housing having an opening allowing the first laser beam, the second laser beam, and the third laser beam having been transmitted through the lens to pass through and containing the first semiconductor laser element, the second semiconductor laser element, the third semiconductor laser element, and the lens inward of the housing; and a light-transmissive member covering the opening, having a second light incident surface and a second light exit surface, and allowing the first laser beam, the second laser beam, and the third laser beam to pass through. The first semiconductor laser element is disposed between the second semiconductor laser element and the third semiconductor laser element. The light-transmissive member has a first diffraction grating provided on the second light incident surface and configured to deflect the second laser beam to allow an optical axis of the second laser beam to come closer to an optical axis of the first laser beam than before the second laser beam passes through the second light incident surface, and a second diffraction grating provided on the second light incident surface and configured to deflect the third laser beam to allow an optical axis of the third laser beam to come closer to the optical axis of the first laser beam than before the third laser beam passes through the second light incident surface.

According to certain embodiments of the present disclosure, a light source device that emits laser beams whose optical axes are closer to each other than optical axes at a region where the laser beams are emitted from respective semiconductor laser elements can be provided.

### BRIEF DESCRIPTION OF THE DRAWINGS

FIG. 1 is a first schematic perspective view illustrating the overall configuration of a light source device according to a first embodiment.

FIG. 2 is a second schematic perspective view illustrating the overall configuration of the light source device according to the first embodiment.

FIG. 3 is a schematic top view illustrating the configuration around a lens included in the light source device according to the first embodiment.

FIG. 4 is a schematic perspective view illustrating the configuration around the lens included in the light source device according to the first embodiment.

FIG. 5 is a schematic perspective view of a light-transmissive member included in the light source device according to the first embodiment.

FIG. 6 is a schematic view of the lens included in the light source device according to the first embodiment taken from a first light incident surface side.

FIG. 7 is a schematic view of the lens included in the light source device according to the first embodiment taken from a first light exit surface side.

FIG. 8 is a schematic cross-sectional view illustrating the configuration of the light-transmissive member included in the light source device according to the first embodiment.

FIG. 9 schematically shows a first laser beam, a second laser beam, and a third laser beam before passing through a second light incident surface of the light-transmissive member included in the light source device according to the first embodiment.

FIG. 10 schematically shows the light intensity distribution along the line X-X of FIG. 9.

FIG. 11 schematically shows the first laser beam, the second laser beam, and the third laser beam before passing through a second light exit surface of the light-transmissive member included in the light source device according to the first embodiment.

FIG. 12 schematically shows the light intensity distribution along the line XII-XII of FIG. 11.

FIG. 13 schematically shows laser beams before passing through a light-diffusing member included in the light source device according to the first embodiment.

FIG. 14 schematically shows the laser beams after passing through the light-diffusing member included in the light source device according to the first embodiment.

FIG. 15 schematically shows the configuration of a display device according to a second embodiment.

### DETAILED DESCRIPTION

A light source device and a display device according to embodiments in the present disclosure will be described in detail referring to the accompanying drawings. The embodiments described below are intended as examples of the light source device and display device to give concrete form to the technical ideas of the present disclosure, but the invention is not limited to the embodiments described below. Unless limitation to specific forms is described, descriptions of the sizes, materials, shapes, and relative positions of constituent units in the embodiments described below are not intended to limit the scope of the present invention to those descriptions, but are rather merely examples for description. Sizes or positional relationships of members illustrated in each drawing may be exaggerated to clarify the descriptions. Furthermore, in the descriptions below, the same name or the same reference numeral represents the same or similar member, and its duplicative description will be omitted as appropriate. The term “dispose” includes not only disposition in direct contact but also includes indirect disposition, such as disposition with another member therebetween.

In each drawing, orthogonal coordinates using an X-axis, a Y-axis, and a Z-axis are used to express directions. The X-axis, the Y-axis, and the Z-axis are orthogonal to one another. The direction of the arrow of the X direction along the X-axis is referred to as a +X direction, and the direction opposite to the +X direction is referred to as a −X direction. The direction of the arrow of the Y direction along the Y-axis is referred to as a +Y direction, and the direction opposite to the +Y direction is referred to as a −Y direction. The direction of the arrow of the Z direction along the Z-axis is referred to as a +Z direction, and the direction opposite to the +Z direction is referred to as a −Z direction. These terms indicating directions and positions are used merely for the sake of ease of description, representing relative directions or relative positions in the referenced drawings. These directional expressions do not limit the orientations during use of the light source device and display device according to embodiments. The orientations during use of the light source device and display device according to embodiments are in any direction.

In the embodiments described below, the expression “along the X-axis, Y-axis, or the Z-axis” as used herein includes the case in which an object is inclined within ±5 degrees with respect to these axes. The expression “along the X-axis, Y-axis, or the Z-axis” as used herein preferably includes the case in which an object is inclined within ±3 degrees or ±1 degree with respect to these axes. In the embodiments, each of the expressions “orthogonal” and “perpendicular” may include a difference within ±5 degrees with respect to 90 degrees. Each of the expressions “orthogonal” and “perpendicular” may preferably include a difference within ±3 degrees or ±1 degree with respect to 90 degrees. In the embodiments, the expression “parallel” may include a difference within ±5 degrees with respect to 180 degrees. The expression “parallel” as used herein may preferably include a difference within ±3 degrees or ±1 degree with respect to 180 degrees. The expression “plan view” as used herein refers to a view of an object from the normal direction of a light-transmissive member included in the light source device according to an embodiment, such as the +Y direction.

### First Embodiment

### <Configuration of Light Source Device According to First Embodiment>

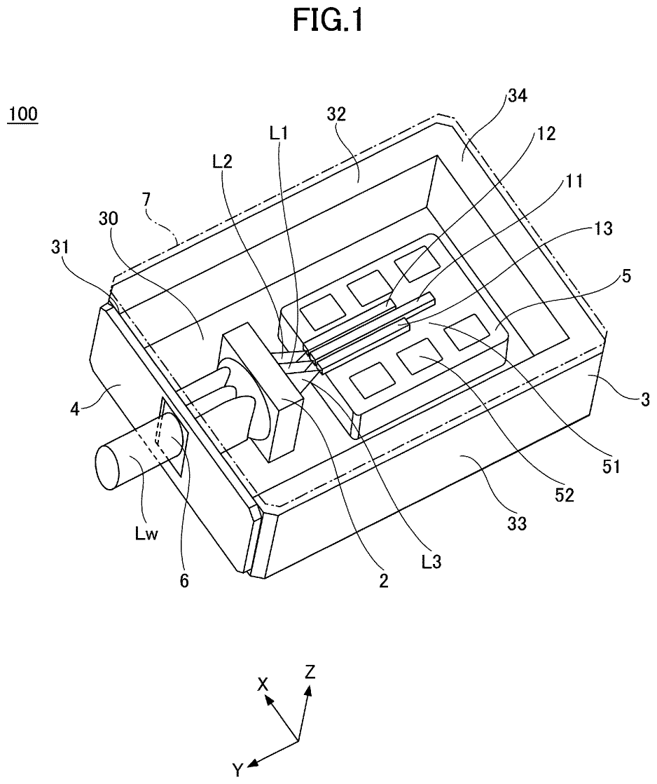

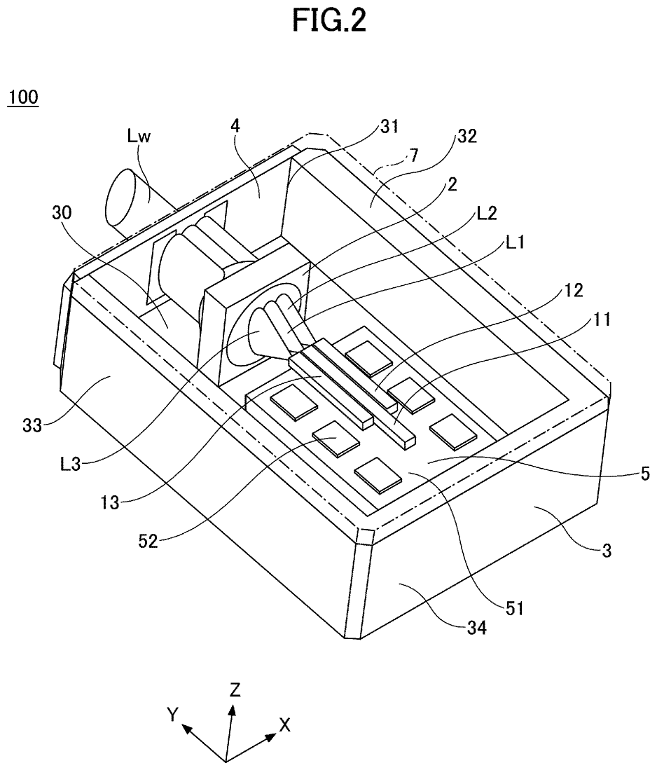

The configuration of a light source device according to a first embodiment will be described with reference to FIGS. 1 to 8. FIG. 1 is a first schematic perspective view illustrating the overall configuration of a light source device 100 according to the first embodiment. FIG. 2 is a second schematic perspective view illustrating the overall configuration of the light source device 100. FIGS. 1 and 2 schematically show the inside of a housing 3 through a lid member 7 for the convenience of description.

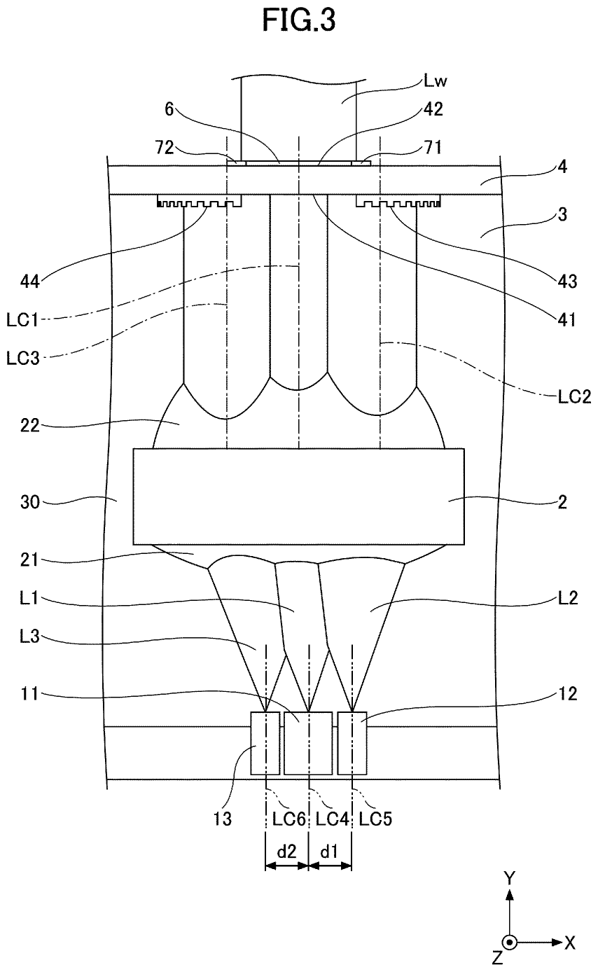

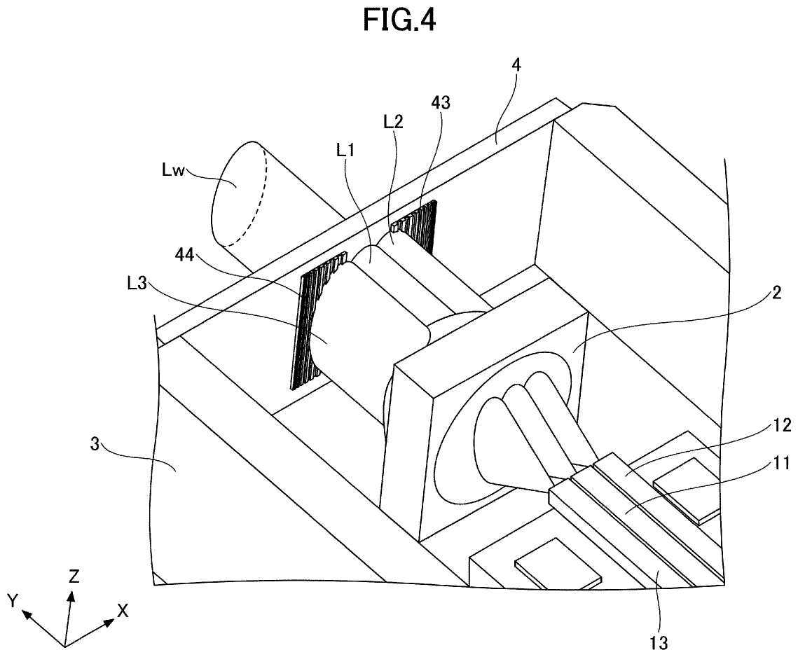

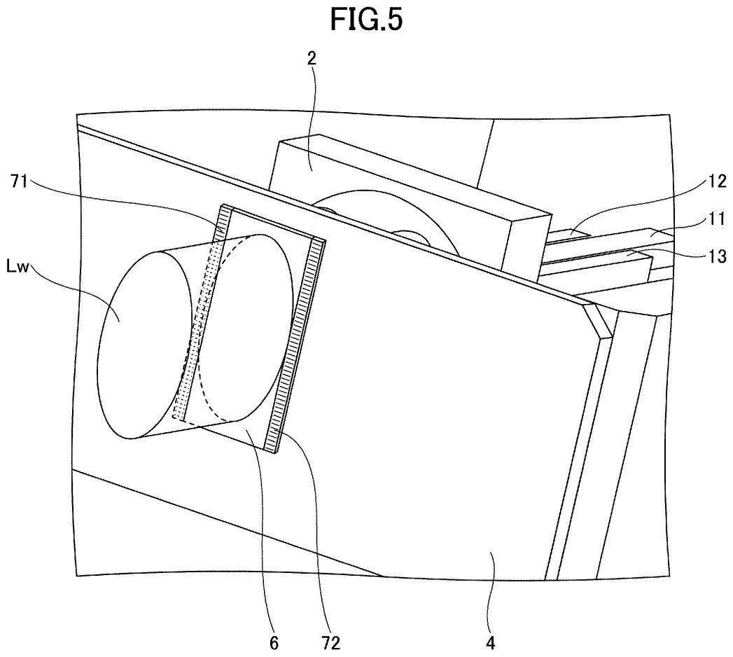

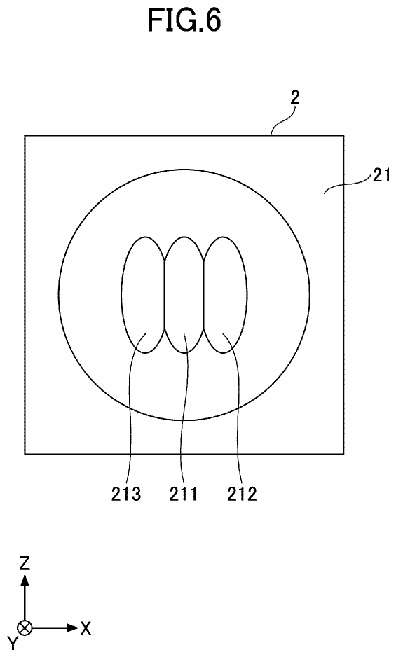

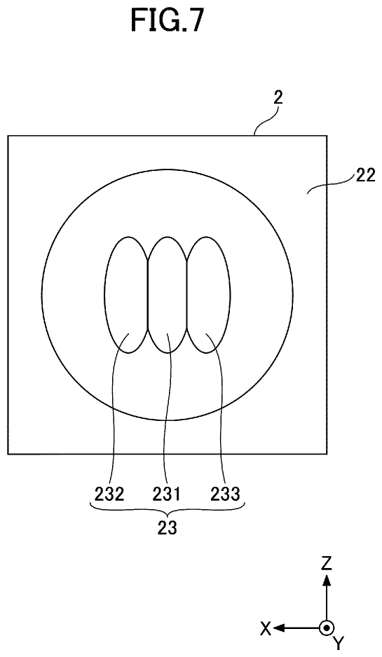

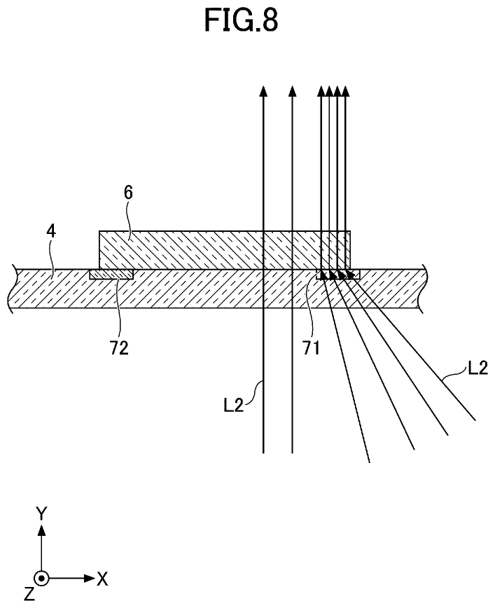

FIG. 3 is a schematic top view illustrating the configuration around a lens 2 included in the light source device 100. FIG. 4 is a schematic perspective view illustrating the configuration around the lens 2 included in the light source device 100. FIG. 5 is a schematic perspective view of a light-transmissive member 4 included in the light source device 100. FIG. 6 is a schematic view of the lens 2 included in the light source device 100 taken from a first light incident surface 21 side. FIG. 7 is a schematic view of the lens 2 included in the light source device 100 taken from a first light exit surface 22 side. FIG. 8 is a schematic cross-sectional view illustrating the configuration of the light-transmissive member 4 included in the light source device 100. FIGS. 3 to 5 show the state in which the upper part (such as the part on the +Z side) of the housing 3 has been removed for the convenience of description.

As shown in FIGS. 1 to 5, the light source device 100 includes a first semiconductor laser element 11 that emits a first laser beam L1 of a first color, a second semiconductor laser element 12 that emits a second laser beam L2 of a second color different from the first color, and a third semiconductor laser element 13 that emits a third laser beam L3 of a third color different from the first color and the second color. The light source device 100 also includes the lens 2 that has a first light incident surface 21 and a first light exit surface 22 and collimates the first laser beam L1, the second laser beam L2, and the third laser beam L3. The light source device 100 further includes a housing 3 having an opening 31 through which the first laser beam L1, the second laser beam L2, and the third laser beam L3 that have been transmitted through the lens 2 pass, and the first semiconductor laser element 11, the second semiconductor laser element 12, third semiconductor laser element 13, and the lens 2 are disposed inward of the housing 3. In addition, the light source device 100 includes the light-transmissive member 4 that covers the opening 31 and has a second light incident surface 41 and a second light exit surface 42, through which the first laser beam L1, the second laser beam L2, and the third laser beam L3 pass. In the present embodiment, the first semiconductor laser element 11 is disposed between the second semiconductor laser element 12 and the third semiconductor laser element 13. The lens 2 is disposed on an upper surface 30 of the housing 3. The upper surface 30 is a mounting surface on which the lens 2 and a supporting member 5 are placed. The first semiconductor laser element 11 is disposed between the second semiconductor laser element 12 and the third semiconductor laser element 13. The light-transmissive member 4 has a first diffraction grating 43 and a second diffraction grating 44. The first diffraction grating 43 is provided on the second light incident surface 41 and deflects the second laser beam L2 so that the optical axis of the second laser beam L2 comes closer to the optical axis of the first laser beam L1 than before the second laser beam L2 passes through the second light incident surface 41. The second diffraction grating 44 is provided on the second light incident surface 41 and deflects the third laser beam L3 so that the optical axis of the third laser beam L3 comes closer to the optical axis of the first laser beam L1 than before the third laser beam L3 passes through the second light incident surface 41.

As the first semiconductor laser element 11 is disposed between the second semiconductor laser element 12 and the third semiconductor laser element 13, the positions where the first laser beam L1, the second laser beam L2, and the third laser beam L3 are emitted are shifted from each other in the X direction. If an optical element is disposed outward of the light source device 100 in order to correct these shifts to align the laser beams on the same axis, the number of components constituting the light source device 100 increases because the optical element is provided. The increase in the number of components may cause an increase in the size of the overall system. It is desirable that the optical axes of laser beams be close to each other at the region where the laser beams exit the light source device 100 because alignment on the same axis is facilitated, which contributes to size reduction in the system. As shown in FIG. 3, the distances between adjacent two optical axes, namely, an optical axis LC4 of the first semiconductor laser element 11, an optical axis LC5 of the second semiconductor laser element 12, and an optical axis LC6 of the third semiconductor laser element 13, may be in a range of 100 μm to 400 μm. For example, a distance d1 between the optical axis LC4 and the optical axis LC5 and a distance d2 between the optical axis LC4 and the optical axis LC6 may be in a range of 100 μm or more and 400 μm or less.

In the present embodiment, the optical axes of the laser beams emitted from the light source device 100 come close to one another because the light-transmissive member 4 has the first diffraction grating 43 and the second diffraction grating 44. The present embodiment can thus provide the light source device 100 that emits laser beams whose optical axes are closer to each other than optical axes at a region where the laser beams are emitted from respective semiconductor laser elements.

The light source device 100 emits a white laser beam Lw provided by mixing the colors of the first laser beam L1, the second laser beam L2, and the third laser beam L3. For example, the first color is red, the second color is green, and the third color is blue. The red light is light with a peak wavelength within the range of 605 nm or more and 750 nm or less. The green light is light with a peak wavelength within the range of 495 nm or more and 570 nm or less. The blue light is light with a peak wavelength within the range of 420 nm or more and 494 nm or less. The white laser beam Lw is light with a color temperature or correlated color temperature of 1,000 K or higher and 10,000 K or lower.

In the example shown in FIGS. 1 to 5, the light source device 100 includes the supporting member 5 that supports the first semiconductor laser element 11, the second semiconductor laser element 12, and the third semiconductor laser element 13. The supporting member 5 is disposed on the upper surface 30 of the housing 3. The first semiconductor laser element 11, the second semiconductor laser element 12, and the third semiconductor laser element 13 are disposed on an upper surface 51 of the supporting member 5. The supporting member 5 includes wiring 52. The light source device 100 also includes a light-diffusing member 6 that is disposed on the second light exit surface 42 and is configured to diffuse the incident first laser beam L1, second laser beam L2, and third laser beam L3 to mix the colors of the respective laser beams. The light source device 100 further has a first metasurface 71 that is provided on the second light exit surface 42, located on the optical path of the second laser beam L2 deflected by the first diffraction grating 43, and arranged such that the refraction angle increases along the outward direction from the center of the second laser beam L2 in the minor axis direction of the second laser beam L2. In addition, the light source device 100 further has a second metasurface 72 that is provided on the second light exit surface 42, located on the optical path of the third laser beam L3 deflected by the second diffraction grating 44, and arranged such that the refraction angle increases along the outward direction from the center of the third laser beam L3 in the minor axis direction of the third laser beam L3.

For example, a Group III-V compound semiconductor is preferably used for each of the first semiconductor laser element 11, the second semiconductor laser element 12, and the third semiconductor laser element 13. Examples of the Group III-V compound semiconductor include a semiconductor including at least one of GaN, InGaN, AlGaN, GaAs, AlGaInP, InGaAsP, and AlGaAs. For example, aluminum nitride or silicon carbide can be used for the supporting member 5.

For example, the lens 2 is produced by processing a resin material or glass material that transmits the first laser beam L1, the second laser beam L2, and the third laser beam L3.

The first light incident surface 21 of the lens 2 is aspheric. As shown in FIG. 6, the first light incident surface 21 includes a first refractive region 211 that reduces the wavefront aberration of the incident first laser beam L1, a second refractive region 212 that reduces the wavefront aberration of the incident second laser beam L2, and a third refractive region 213 that reduces the wavefront aberration of the incident third laser beam L3. The sagittas of the first refractive region 211, the second refractive region 212, and the third refractive region 213 are different from one another. The sagittas of the second refractive region 212 and the third refractive region 213 may be the same.

The lens 2 has a third diffraction grating 23 on the first light exit surface 22. The third diffraction grating 23 includes a first diffractive region 231 that diffracts the incident first laser beam L1, a second diffractive region 232 that diffracts the incident second laser beam L2, and a third diffractive region 233 that diffracts the incident third laser beam L3. The periods of the diffraction gratings of the first diffractive region 231, the second diffractive region 232, and the third diffractive region 233 are different from one another. The periods of the diffraction gratings of the second diffractive region 232 and the third diffractive region 233 may be the same. The diffraction grating includes a plurality of grooves having a period in the X direction and extending in the Z direction.

The magnitude of the refraction angle of light with a predetermined wavelength passing through the refractive region differs from the magnitude of the diffraction angle passing through the diffractive region. This is because the wavelength dependence properties of the refraction angle and the diffraction angle are opposite to each other. The refraction angle increases as the wavelength decreases, and the diffraction angle decreases as the wavelength decreases. The laser beams passing through the lens 2 pass through the first refractive region 211, the second refractive region 212, or the third refractive region 213 of the first light incident surface 21 and are refracted at predetermined refraction angles of the respective colors. At this time, the refraction angle varies according to the color, and the refraction angle increases as the wavelength decreases. Subsequently, the laser beams pass through the first diffractive region 231, the second diffractive region 232, or the third diffractive region 233 of the first light exit surface 22 and are diffracted at predetermined diffraction angles of the respective colors. At this time, the diffraction angle varies according to the color, and the diffraction angle decreases as the wavelength decreases. Accordingly, as the lens 2 has the third diffraction grating 23, the diffraction by the third diffraction grating 23 cancels out the differences in deflection angle between the colors (that is, differences in refraction angle between the colors) caused by refraction by the first refractive region 211, the second refractive region 212, and the third refractive region 213. In the light source device 100, the chromatic aberrations of the first laser beam L1, the second laser beam L2, and the third laser beam L3 emitted from the lens 2 can therefore be corrected.

Accordingly, the aberrations of the first laser beam L1, the second laser beam L2, and the third laser beam L3 exiting the lens 2 are reduced, and the light-transmissive member 4 located downstream of the lens 2 appropriately mixes the colors of the first laser beam L1, the second laser beam L2, and the third laser beam L3, so that the unevenness in color of the white light emitted from the light source device 100 is further reduced.

The housing 3 is produced, for example, by molding a ceramic or metal. In the light source device 100, the light-transmissive member 4 can also serve as a lateral surface of the housing 3, so that the number of components can be reduced. For example, the housing 3 may be produced by injection-molding a resin that blocks the first laser beam L1, the second laser beam L2, and the third laser beam L3. By forming the supporting member 5 from a resin, the costs can be reduced as compared with the case of a ceramic or metal.

In the example shown in FIGS. 1 and 2, the housing 3 has a substantially rectangular outer shape in a top view. The housing 3 includes a first lateral wall 32, a second lateral wall 33 opposite to the first lateral wall 32, and a third lateral wall 34. The light-transmissive member 4 is located opposite the third lateral wall 34 and attached to the first lateral wall 32 and the second lateral wall 33. The housing 3 is sealed with the lid member 7 opposite to the upper surface 30 of the housing 3. The outer shape of the housing 3 in a top view is not limited to the substantially rectangular shape, and can be appropriately changed. The opening 31 having any size may be located at any position of the housing 3.

The light-transmissive member 4 covers the opening 31 of the housing 3. The light-transmissive member 4 includes the first diffraction grating 43 and the second diffraction grating 44. The first diffraction grating 43 is provided on the second light incident surface 41 and deflects the second laser beam L2 so that the optical axis LC2 of the second laser beam L2 comes closer to the optical axis LC1 of the first laser beam L1 than before the second laser beam L2 passes through the second light incident surface 41. The second diffraction grating 44 is provided on the second light incident surface 41 and deflects the third laser beam L3 so that the optical axis LC3 of the third laser beam L3 comes closer to the optical axis LC1 of the first laser beam L1 than before the third laser beam L3 passes through the second light incident surface 41.

For example, the light-transmissive member 4 is produced by etching glass that transmits the first laser beam L1, the second laser beam L2, and the third laser beam L3. The light-transmissive member 4 has a substantially rectangular shape in a plan view. The shape of the light-transmissive member 4 is not limited to the substantially rectangular shape but can be appropriately changed according to the shape of the opening 31.

In the first diffraction grating 43 and the second diffraction grating 44 of the light-transmissive member 4, the grating pitch decreases to increase the diffraction angle as the position in the incident elliptical laser beam goes outward in the minor axis direction. The outer rays of the second laser beam L2 and the third laser beam L3 are therefore deflected inward and overlap the first laser beam L1.

The second laser beam L2 has the minor axis direction and the major axis direction. The third laser beam L3 has the minor axis direction and the major axis direction. The minor axis directions of the second laser beam L2 and the third laser beam L3 correspond to the X direction. The major axis directions of the second laser beam L2 and the third laser beam L3 correspond to the Z direction. As shown in FIG. 3, in a region that overlaps the second laser beam L2 and does not overlap the first laser beam L1, the grating pitch of the first diffraction grating 43 decreases along the outward direction from the center of the second laser beam L2 in the minor axis direction of the second laser beam L2. In a region that overlaps the third laser beam L3 and does not overlap the first laser beam L1, the grating pitch of the second diffraction grating 44 decreases along the outward direction from the center of the third laser beam L3 in the minor axis direction of the third laser beam L3. That is, the first diffraction grating 43 and the second diffraction grating 44 are binary diffraction gratings. The diffraction angle therefore increases as the position in the elliptical beam in the minor axis direction goes toward the periphery of the elliptical beam. The outer rays of the second laser beam L2 and the third laser beam L3 are deflected inward, and the optical axes of the second laser beam L2 and the third laser beam L3 become close to the optical axis of the first laser beam.

In the light source device 100, the travel direction of the second laser beam L2 deflected by the first diffraction grating 43 can be adjusted using the first metasurface 71. Similarly, in the light source device 100, the travel direction of the third laser beam L3 deflected by the second diffraction grating 44 can be adjusted using the second metasurface 72. Accordingly, in the light source device 100, alignment of the laser beams on the same axis in a downstream optical element is further facilitated.

The first metasurface 71 preferably further allows the optical axis LC2 of the second laser beam L2 to be parallel to the optical axis LC1 of the first laser beam L1 in a plan view, and the second metasurface 72 preferably further allows the optical axis LC3 of the third laser beam L3 to be parallel to the optical axis LC1 of the first laser beam L1 in a plan view. This configuration can further facilitate the alignment on the same axis in a downstream optical element because the optical axes of the laser beams emitted from the light source device 100 are parallel to one another.

The first metasurface 71 and the second metasurface 72 are preferably located so as to overlap the light-diffusing member 6 in a plan view as shown in FIG. 8. By diffusing the first laser beam L1, the second laser beam L2, and the third laser beam L3 with the light-diffusing member 6, the colors of the first laser beam L1, the second laser beam L2, and the third laser beam L3 can be appropriately mixed. By mixing these colors, the white laser beam Lw is provided.

In the first metasurface 71 and the second metasurface 72 of the light-transmissive member 4, the diameters and heights of cells (such as cylinders) with sizes of the order of wavelength gradually change such that the refraction angle increases as the position in the incident elliptical laser beam goes outward in the minor axis direction. Each of the first metasurface 71 and the second metasurface 72 is an optical component having a structure in which cells (such as cylinders) with sizes of the order of wavelength are arranged in a pattern on a flat plate. As the cells with sizes of the order of wavelength are formed in small areas, the first metasurface 71 and the second metasurface 72 can control the amount of phase shift of light and change the direction of the light.

As shown in FIG. 8, the travel direction of a component of the second laser beam L2 passing through the first metasurface 71 is corrected, and this component becomes parallel to a component of the second laser beam L2 not passing through the first metasurface 71. Similarly, the travel direction of a component of the third laser beam L3 passing through the second metasurface 72 is corrected, and this component becomes parallel to a component of the third laser beam L3 not passing through the second metasurface 72. The first laser beam L1, the second laser beam L2, and the third laser beam L3 can therefore be parallel light.

The first metasurface 71 is preferably located at the following position. That is, the first metasurface 71 is preferably located at a position on the second light exit surface 42 at which the intensity of part of the second laser beam L2 that is incident on a region not overlapping the first laser beam L1 is 1% or more, more preferably 0.1% or more, of the peak intensity of the second laser beam L2. The second metasurface 72 is preferably located at the following position. That is, the second metasurface 72 is preferably located at a position on the second light exit surface 42 at which the intensity of part of the third laser beam L3 that is incident on a region not overlapping the first laser beam L1 is 1% or more, more preferably 0.1% or more, of the peak intensity of the third laser beam L3. This arrangement can allow the second laser beam L2 and the third laser beam L3 to efficiently overlap each other.

For example, the light-diffusing member 6 is produced by injection-molding a resin that transmits the first laser beam L1, the second laser beam L2, and the third laser beam L3. Glass that transmits the first laser beam L1, the second laser beam L2, and the third laser beam L3 may be used for the light-diffusing member 6. The light-diffusing member 6 has a light-diffusing property because of a rough surface, light-diffusing particles provided on the surface or inside the member, or the like.

In the present embodiment, the colors of the respective laser beams can be more appropriately mixed because the light source device 100 includes the light-diffusing member 6. Further, diffusion of the laser beams can reduce the coherency of the laser beam and reduce speckle noise.

<operation of Light Source Device>

In the example shown in FIGS. 1 to 5, the first laser beam L1 emitted from the first semiconductor laser element 11 enters the lens 2 and exits the lens 2 through the first refractive region 211 and the first diffractive region 231 of the lens 2. The second laser beam L2 emitted from the second semiconductor laser element 12 enters the lens 2 and exits the lens 2 through the second refractive region 212 and the second diffractive region 232 of the lens 2. The third laser beam L3 emitted from the third semiconductor laser element 13 enters the lens 2 and exits the lens 2 through the third refractive region 213 and the third diffractive region 233 of the lens 2.

The first laser beam L1 emitted from the lens 2 enters the light-transmissive member 4 and exits the light-transmissive member 4 through the second light incident surface 41 and the second light exit surface 42. The second laser beam L2 exiting the lens 2 enters the light-transmissive member 4 and exits the light-transmissive member 4 through the first diffraction grating 43 and the first metasurface 71. The third laser beam L3 exiting the lens 2 enters the light-transmissive member 4 and exits the light-transmissive member 4 through the second diffraction grating 44 and the second metasurface 72.

Along the optical path from the incidence on the light-transmissive member 4 to exit from the light-transmissive member 4, the optical axis LC1 of the first laser beam, the optical axis LC2 of the second laser beam, and the optical axis LC3 of the third laser beam come close to one another, and the beams exit the light-transmissive member 4 as beams parallel to one another.

The first laser beam L1, the second laser beam L2, and the third laser beam L3 exiting the light-transmissive member 4 enter the light-diffusing member 6. The colors of the laser beams are thus mixed, and the light source device 100 emits the white laser beam Lw provided by mixing the colors of the first laser beam L1, the second laser beam L2, and the third laser beam L3. At this time, optical axes of the respective laser beams are on the same axis.

<effect of Light Source Device 100>

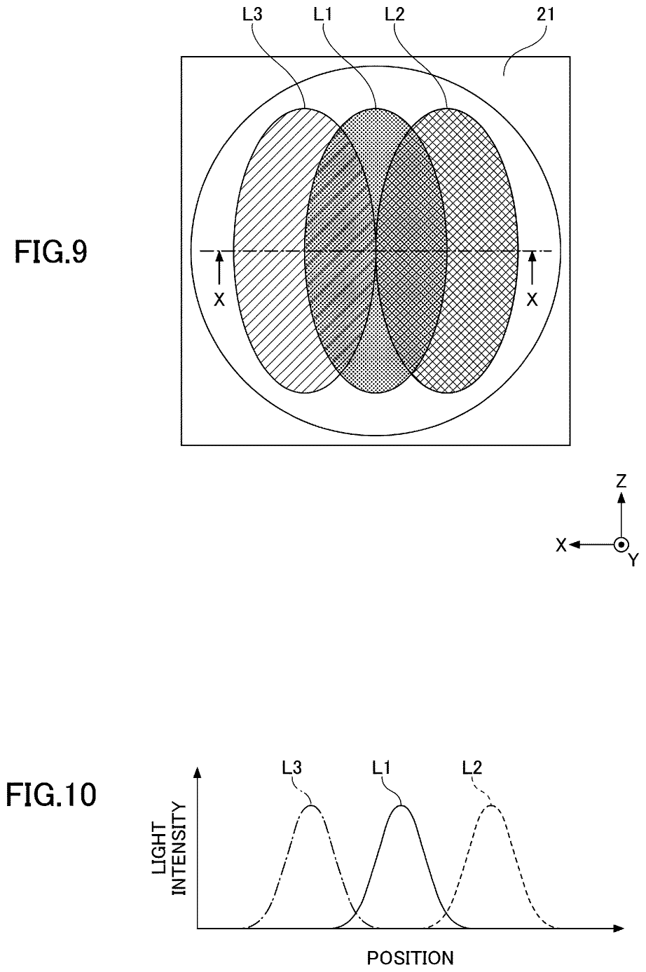

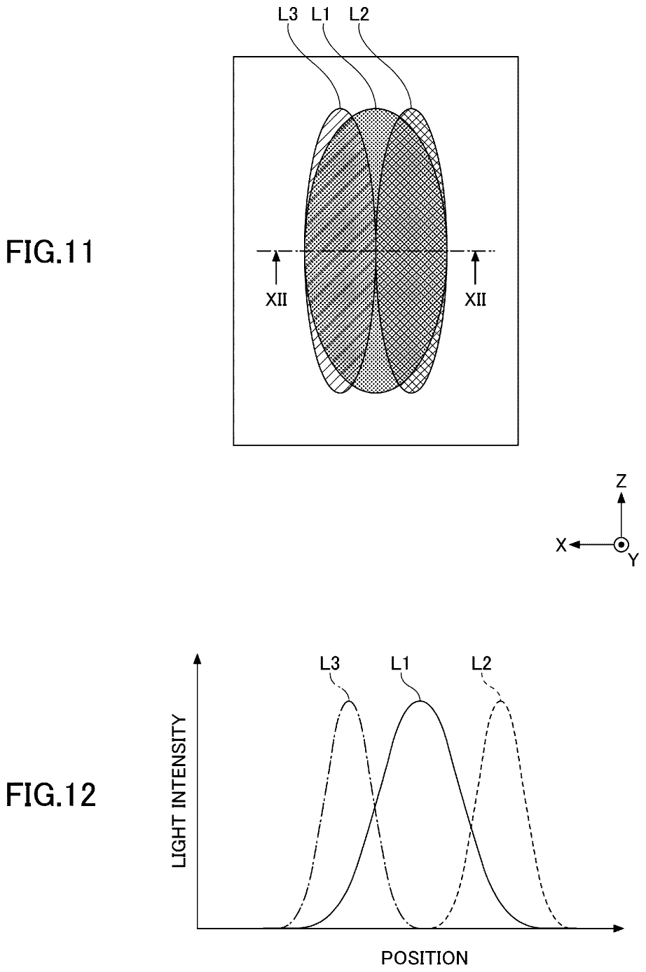

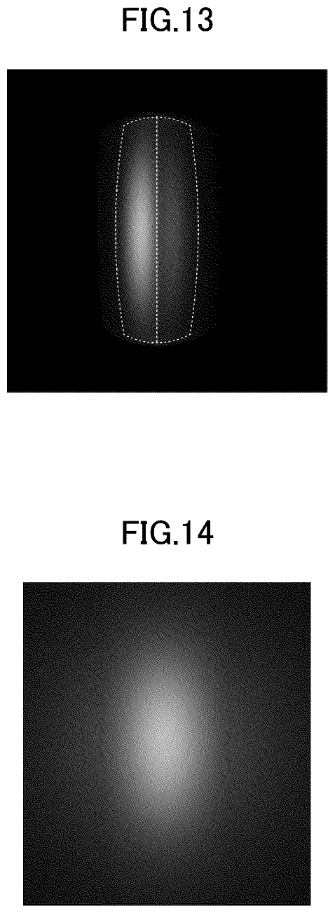

The effect of the light source device 100 will be described referring to FIGS. 9 to 14. FIG. 9 schematically shows the first laser beam L1, the second laser beam L2, and the third laser beam L3 before passing through the second light incident surface 41 of the light-transmissive member 4. FIG. 10 schematically shows the light intensity distribution along the line X-X of FIG. 9. FIG. 11 schematically shows the first laser beam L1, the second laser beam L2, and the third laser beam L3 before passing through the second light exit surface 42 of the light-transmissive member 4. FIG. 12 schematically shows the light intensity distribution along the line XII-XII of FIG. 11. FIG. 13 schematically shows simulation of laser beams before passing through the light-diffusing member 6 included in the light source device 100. FIG. 14 schematically shows simulation of the laser beams after passing through the light-diffusing member 6 included in the light source device 100.

FIGS. 9 and 11 schematically show simulation results of the first laser beam L1, the second laser beam L2, and the third laser beam L3 in a plan view. FIGS. 10 and 12 schematically show simulation results of the light intensity distribution. FIGS. 13 and 14 schematically show simulation results of the laser beams in a plan view. The dotted lines in FIG. 13 indicate an approximate shape of each beam.

The second laser beam L2 shown in FIGS. 11 and 12 is closer to the first laser beam L1 than the second laser beam L2 shown in FIGS. 9 and 10. The third laser beam L3 shown in FIGS. 11 and 12 is closer to the first laser beam L1 than the third laser beam L3 shown in FIGS. 9 and 10. As described above, the light-transmissive member 4 can allow each of the incident second laser beam L2 and third laser beam L3 to be close to the first laser beam L1.

As shown by the simulation results of FIG. 13, the first laser beam L1 overlaps the second laser beam L2, and the first laser beam L1 overlaps the third laser beam L3. The overlap between the second laser beam L2 and the third laser beam L3 is smaller than the above overlaps. In the example shown in FIG. 14, the colors of the first laser beam L1, the second laser beam L2, and the third laser beam L3 are mixed better than in the example shown in FIG. 13. As described above, the light-diffusing member 6 can diffuse the incident first laser beam L1, second laser beam L2, and third laser beam L3 to mix the colors of the respective laser beams.

An embodiment in which the first laser beam L1, the second laser beam L2, and the third laser beam L3 are extracted in the Y direction has been described as the first embodiment, but the present disclosure is not limited to this embodiment. For example, an upward-reflecting mirror may be provided on the upper surface 30 of the housing 3 to direct each laser beam upward. In this case, a part of the lid member 7 may be the light-transmissive member 4 having the second light incident surface 41 and the second light exit surface 42, or the light-transmissive member 4 may be disposed on the light incident surface side or light exit surface side of the lid member 7. Also in this case, the light source device that emits laser beams whose optical axes are closer to each other than the optical axes at the region where the laser beams are emitted from respective semiconductor laser elements can be provided. The light-diffusing member 6 may be further disposed on the light exit surface side of the lid member 7. Also in this case, the colors of the first laser beam L1, the second laser beam L2, and the third laser beam L3 are appropriately mixed, so that the unevenness in color of the white light emitted from the light source device 100 is further reduced.

In the first embodiment, the light source device is not limited to the configuration including the first semiconductor laser element 11 that emits the first laser beam L1, the second semiconductor laser element 12 that emits the second laser beam L2, and the third semiconductor laser element 13 that emits the third laser beam L3. In other words, the light source device may be configured with two semiconductor laser elements.

### Second Embodiment

Subsequently, a display device according to a second embodiment will be described. The same term or reference numeral as in the embodiment described above represents the same or similar member or configuration, and its detailed description will be omitted as appropriate.

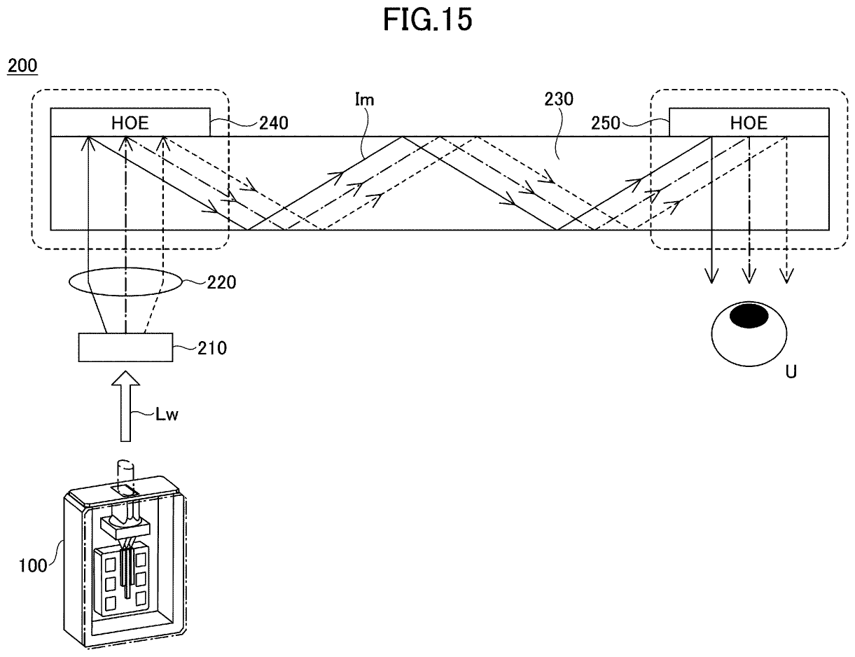

FIG. 15 schematically shows the configuration of a display device 200 according to the second embodiment. The display device 200 according to the present embodiment includes the light source device 100 and displays an image using the white laser beam emitted from the light source device 100. In the example shown in FIG. 15, the display device 200 is a head mounted display (HMD) worn by an observer, which displays an image visible to the observer.

The display device 200 includes the light source device 100 that emits the white laser beam Lw, a spatial modulator 210 that performs spatial modulation of the white laser beam Lw emitted from the light source device 100, and a condenser lens 220 that transmits light modulated by the spatial modulator 210. The display device 200 also includes a light-guiding member 230 that guides light transmitted through the condenser lens 220, a first holographic optical device (HOE) 240 that is optically coupled to the light-guiding member 230, and a second HOE 250 that allows the light to be emitted from the light-guiding member 230.

For example, the light source device 100, the spatial modulator 210, and the condenser lens 220 are arranged in temples of a support with the shape of glasses. The light-guiding member 230, the first HOE 240, and the second HOE 250 are arranged in eyeglass lenses or the like provided in the frame of the support with the shape of glasses.

The spatial modulator 210 performs spatial modulation of the white laser beam Lw to form image light Im, which constitutes an image viewable by a wearer U of the display device 200. The image light Im is incident on the light-guiding member 230 through the condenser lens 220. The image light Im incident on the light-guiding member 230 is deflected by the first HOE 240 and coupled to the light-guiding member 230. The image light Im coupled to the light-guiding member 230 is guided inside the light-guiding member 230. Part of the image light Im that has reached the second HOE 250 in the image light Im guided inside the light-guiding member 230 is deflected by the second HOE 250 and exits the light-guiding member 230. The image light Im emitted from the light-guiding member 230 enters the eyes of the wearer U. The wearer U can view the image based on the incident image light Im.

The light source device 100 emits laser beams whose optical axes are closer to each other than the optical axes at the region where the laser beams are emitted from respective semiconductor laser elements. Accordingly, the display device 200 can display a color image with reduced unevenness in color of the white light using the white laser beam Lw provided by mixing the colors of the first laser beam L1, the second laser beam L2, and the third laser beam L3.

The display device 200 is not limited to a head mounted display but may be augmented reality (AR) glasses, virtual reality (VR) glasses, a projector, a heads-up display (HUD), or the like.

Preferable embodiments have been described above in detail, but the embodiments described above are not limiting. Various modification and replacement can be performed on the embodiments described above within the scope of the claims.

The numbers for the ordinal numerals, quantities, and the like used in the description of the embodiments are all examples for specifically describing the technique of the present disclosure, and the present disclosure is not limited to the exemplified numbers. The relationship of connection between components is an example given for specifically describing the techniques of the present disclosure and does not limit the relationship of connection for implementing the function of the present disclosure.

The light source device of the present disclosure can provide a light source device that emits laser beams whose optical axes are closer to each other than the optical axes at the region where the laser beams are emitted from respective semiconductor laser elements. The light source device of the present disclosure can therefore be suitably used as a light source device in various devices, equipment, or systems using laser beams. For example, the light source device of the present disclosure can be suitably used as a light source device for a display device such as a projector and a heads-up display or a display device that is worn on the head, such as a head mounted display. The light source device of the present disclosure can also be used for a light source device and a display device in a lighting system such as a light fixture, smart lighting, and energy saving lighting, a drawing device installed in a vehicle or an air vehicle, a spatial three-dimensional drawing device, an in-water drawing system, and the like.

1. A light source device comprising:
a first semiconductor laser element configured to emit a first laser beam of a first color;
a second semiconductor laser element configured to emit a second laser beam of a second color different from the first color;
a third semiconductor laser element configured to emit a third laser beam of a third color different from both the first color and the second color;
a lens having a first light incident surface and a first light exit surface and being configured to collimate the first laser beam, the second laser beam, and the third laser beam;
a housing defining an opening allowing the first laser beam, the second laser beam, and the third laser beam that have been transmitted through the lens to pass therethrough, the housing containing therein the first semiconductor laser element, the second semiconductor laser element, the third semiconductor laser element; and
a light-transmissive member covering the opening, having a second light incident surface and a second light exit surface, and allowing the first laser beam, the second laser beam, and the third laser beam to pass therethrough; wherein:
the first semiconductor laser element is disposed between the second semiconductor laser element and the third semiconductor laser element; and
the light-transmissive member comprises:
a first diffraction grating on the second light incident surface and configured to deflect the second laser beam to allow an optical axis of the second laser beam to come closer to an optical axis of the first laser beam than before the second laser beam passes through the second light incident surface, and
a second diffraction grating on the second light incident surface and configured to deflect the third laser beam to allow an optical axis of the third laser beam to come closer to the optical axis of the first laser beam than before the third laser beam passes through the second light incident surface.

2. The light source device according to claim 1, wherein:
the second laser beam has a minor axis direction and a major axis direction;
the third laser beam has a minor axis direction and a major axis direction;
in a region of the first diffraction grating overlapping the second laser beam and not overlapping the first laser beam, a grating pitch of the first diffraction grating decreases along an outward direction from a center of the second laser beam in the minor axis direction of the second laser beam; and
in a region of the second diffraction grating overlapping the third laser beam and not overlapping the first laser beam, a grating pitch of the second diffraction grating decreases along an outward direction from a center of the third laser beam in the minor axis direction of the third laser beam.

3. The light source device according to claim 1, further comprising:
a first metasurface on the second light exit surface, located on an optical path of the second laser beam deflected by the first diffraction grating, and arranged such that a refraction angle increases along an outward direction from a center of the second laser beam in a minor axis direction of the second laser beam; and
a second metasurface on the second light exit surface, located on an optical path of the third laser beam deflected by the second diffraction grating, and arranged such that a refraction angle increases along an outward direction from a center of the third laser beam in a minor axis direction of the third laser beam.

4. The light source device according to claim 3, wherein:
the first metasurface further allows the optical axis of the second laser beam to be parallel to the optical axis of the first laser beam in a plan view; and
the second metasurface further allows the optical axis of the third laser beam to be parallel to the optical axis of the first laser beam in a plan view.

5. The light source device according to claim 1, further comprising:
a light-diffusing member disposed on the second light exit surface and configured to diffuse the first laser beam, the second laser beam, and the third laser beam incident on the light-diffusing member to mix the first, second, and third colors.

6. The light source device according to claim 5, wherein the first color is red, the second color is green, and the third color is blue.

7. The light source device according to claim 3, further comprising:
a light-diffusing member disposed on the second light exit surface and configured to diffuse the first laser beam, the second laser beam, and the third laser beam incident on the light-diffusing member to mix the first, second, and third colors,
wherein the first metasurface and the second metasurface are located so as to overlap the light-diffusing member in a plan view.

8. The light source device according to claim 1, wherein:
the first light incident surface of the lens is aspheric; and
the first light incident surface includes:
a first refractive region configured to reduce wavefront aberration of the first laser beam incident on the first refractive region,
a second refractive region configured to reduce wavefront aberration of the second laser beam incident on the second refractive region, and
a third refractive region configured to reduce wavefront aberration of the third laser beam incident on the third refractive region.

9. The light source device according to claim 8, wherein:
the lens comprises a third diffraction grating on the first light exit surface; and
the third diffraction grating includes:
a first diffractive region configured to diffract the first laser beam incident on the first diffractive region,
a second diffractive region configured to diffract the second laser beam incident on the second diffractive region, and
a third diffractive region configured to diffract the third laser beam incident on the third diffractive region.

10. The light source device according to claim 1, wherein each of a distance between an optical axis of the first semiconductor laser element and an optical axis of the second semiconductor laser element, and a distance between the optical axis of the first semiconductor laser element and an optical axis of the third semiconductor laser element is in a range of 100 μm or more and 400 μm or less.

11. A display device comprising the light source device according to claim 1, the display device being configured to display an image using a white laser beam emitted from the light source device.
